(19) United States
(12) Patent Application Publication
(10) Pub. No.: US 2015/0279877 A1
(43) Pub. Date: Oct. 1, 2015

(54) SOLID STATE IMAGING DEVICE AND METHOD FOR MANUFACTURING SAME

(71) Applicant: Kabushiki Kaisha Toshiba, Minato-ku (JP)

(72) Inventors: Rikyu IKARIYAMA, Chigasaki (JP); Hiroyuki FUKUMIZU, Yokohama (JP); Noriteru YAMADA, Oita (JP); Naohiro TSUDA, Oita (JP); Kazunori KAKEHI, Oita (JP)

(73) Assignee: Kabushiki Kaisha Toshiba, Minato-ku (JP)

(21) Appl. No.: 14/626,043

(22) Filed: Feb. 19, 2015

(30) Foreign Application Priority Data
Mar. 25, 2014 (JP) 2014-061140

(51) Int. Cl. H01L 27/146

(52) U.S. Cl. CPC H01L 27/1461; H01L 27/14627; H01L 27/14625; H01L 27/14685; H01L 27/14689

(57) ABSTRACT

According to one embodiment, a solid state imaging device includes a semiconductor layer, a first layer, a second layer and third layer. The semiconductor layer performs photoelectric conversion. The first layer has a first refractive index. The second layer is provided between the first layer and the semiconductor layer, the second layer includes a metal oxide and has a second refractive index not greater than the first refractive index. The third layer is provided between the first layer and the second layer. The third layer has a third refractive index and includes an element bonding covalently with oxygen. The third refractive index is not greater than the first refractive index.

### CROSS-REFERENCE TO RELATED APPLICATION

This application is based upon and claims the benefit of priority from Japanese Patent Application No.2014-061140, filed on Mar. 25, 2014; the entire contents of which are incorporated herein by reference.

### FIELD

Embodiments described herein relate generally to a solid state imaging device and a method for solid state imaging device.

### BACKGROUND

It is desirable to improve the characteristics of solid state imaging devices.

### BRIEF DESCRIPTION OF THE DRAWINGS

FIG. 1 is a schematic cross-sectional view showing a solid state imaging device according to a first embodiment;

FIG. 2A and FIG. 2B are schematic cross-sectional views showing a method for manufacturing the solid state imaging device according to the first embodiment;

FIG. 3A to FIG. 3C are schematic views showing characteristics of the solid state imaging device according to the first embodiment;

FIG. 4 is a schematic cross-sectional view showing a solid state imaging device according to a second embodiment; and

FIG. 5 is a flowchart showing a method for manufacturing a solid state imaging device according to a third embodiment.

### DETAILED DESCRIPTION

According to one embodiment, a solid state imaging device includes a semiconductor layer, a first layer, a second layer and third layer. The semiconductor layer performs photoelectric conversion. The first layer has a first refractive index. The second layer is provided between the first layer and the semiconductor layer, the second layer includes a metal oxide and has a second refractive index not greater than the first refractive index. The third layer is provided between the first layer and the second layer. The third layer has a third refractive index and includes an element bonding covalently with oxygen. The third refractive index is not greater than the first refractive index.

Embodiments of the invention will now be described with reference to the drawings.

The drawings are schematic or conceptual; and the relationships between the thicknesses and widths of portions, the proportions of sizes between portions, etc., are not necessarily the same as the actual values thereof. Also, the dimensions and/or the proportions may be illustrated differently between the drawings, even in the case where the same portion is illustrated.

In the drawings and the specification of the application, components similar to those described in regard to a drawing thereinabove are marked with like reference numerals, and a detailed description is omitted as appropriate.

### First Embodiment

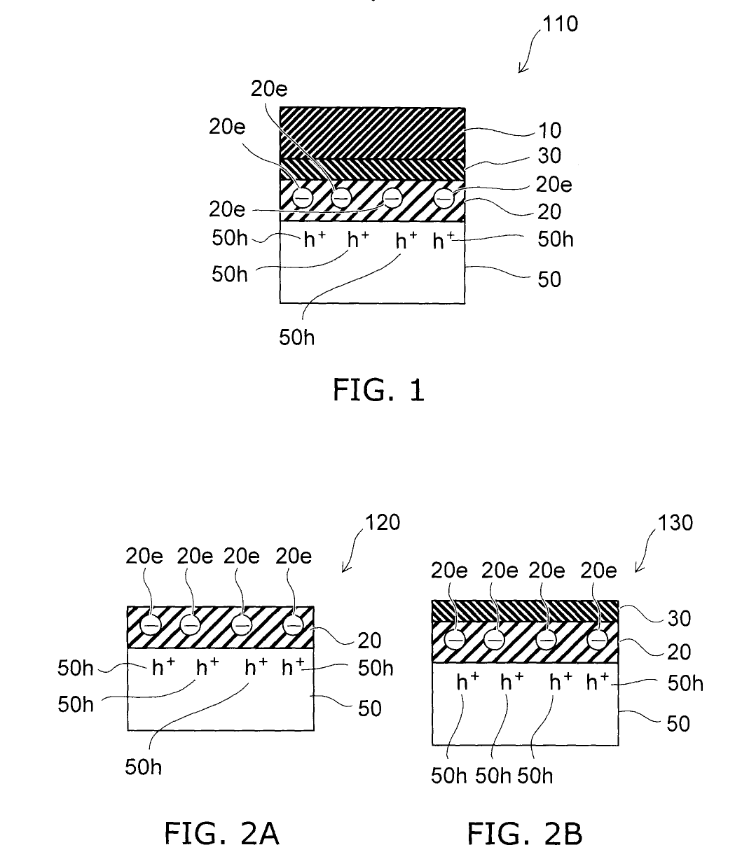

FIG. 1 is a schematic cross-sectional view showing a solid state imaging device according to a first embodiment.

As shown in FIG. 1, a semiconductor layer 50, a first layer 10, a second layer 20, and a third layer 30 are provided in the solid state imaging device 110 according to the embodiment.

The semiconductor layer 50 performs photoelectric conversion. For example, the semiconductor layer 50 stores holes 50h (the apparent charge where electrons are removed).

The first layer 10 has a first refractive index. The first layer 10 has low reflectance for the light that is incident. The first layer 10 includes, for example, one of titanium oxide or tantalum oxide. For example, a substance having a refractive index not less than 2 is used as the first layer 10.

The second layer 20 includes a metal oxide. The second layer 20 has a second refractive index that is not greater than the first refractive index. For example, the second layer 20 stores negative charge 20e. The second layer 20 includes, for example, at least one of hafnium oxide, zirconium oxide, aluminum oxide, titanium oxide, or tantalum oxide.

The third layer 30 includes an element that bonds covalently with oxygen. The third layer 30 has a third refractive index that is not greater than the first refractive index. The third layer 30 includes, for example, at least one of silicon oxide, silicon nitride, or silicon oxynitride.

FIG. 2A and FIG. 2B are schematic cross-sectional views showing a method for manufacturing the solid state imaging device according to the first embodiment.

As shown in FIG. 2A, the second layer 20 is formed on the semiconductor layer 50.

As shown in FIG. 2B, the third layer 30 is formed on the second layer 20. At this time, the state of the negative charge 20e of the second layer 20 being stored is maintained. The third layer 30 is formed by, for example, chemical vapor deposition (CVD). The third layer 30 is formed by, for example, atomic layer deposition (ALD). The first layer 10 is formed on the third layer 30. In other words, the solid state imaging device 110 according to the first embodiment is formed. The first layer 10 is formed using, for example, physical vapor deposition (PVD).

The formation conditions of the third layer 30 are milder than the formation conditions of the first layer 10. Therefore, damage of the second layer 20 substantially does not occur even when the third layer 30 is formed on the second layer 20. The third layer 30 protects the second layer 20. Damage of the second layer 20 substantially does not occur even when the first layer 10 is formed on the second layer 20 protected by the third layer 30. In the embodiment, the negative charge 20e of the second layer 20 is in the desired state.

On the other hand, there is a reference example in which the first layer 10 is formed on the second layer 20 without forming the third layer 30. In the reference example, the second layer 20 is damaged when forming the first layer 10. For example, the negative charge 20e of the second layer 20 is no longer in the desired state. In other words, the negative charge 20e decreases. Therefore, the holes 50h decrease. Thereby, for example, an amount An of dark current of the solid state imaging device increases. For example, white blemishes increase. The dark current is the leakage current that flows in the solid state imaging device when there is no light. The white blemishes are point defects that occur due to the leakage current.

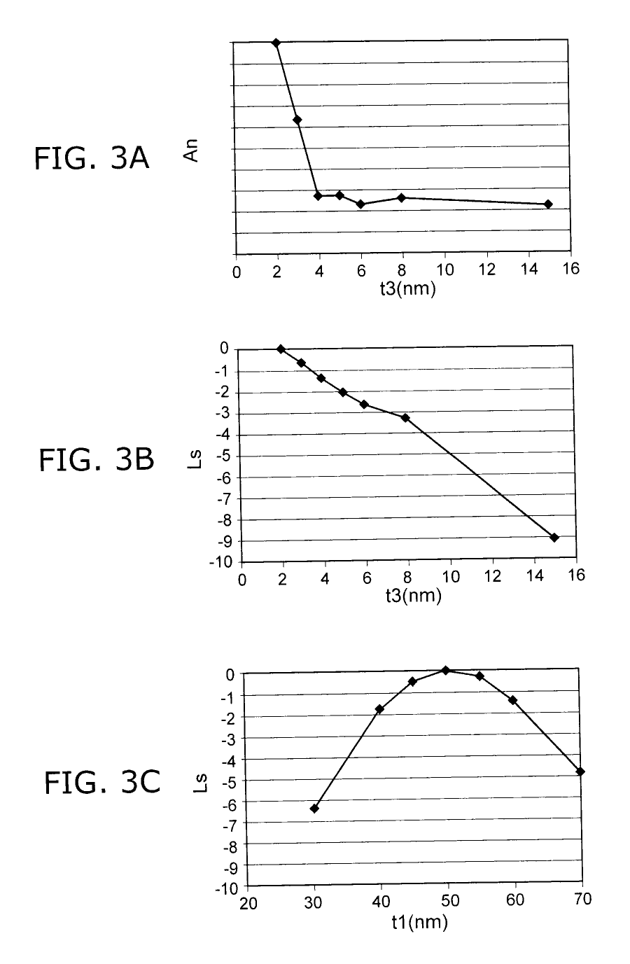

FIG. 3A to FIG. 3C are schematic views showing characteristics of the solid state imaging device according to the first embodiment.

FIG. 3A shows the amount An of the dark current of the solid state imaging device 110. The horizontal axis of FIG. 3A is a thickness t3 of the third layer 30. The vertical axis of FIG. 3A is the amount An of the dark current.

As shown in FIG. 3A, the amount An of the dark current changes when the thickness t3 is changed. The amount An of the dark current is higher when the thickness t3 is less than 3 nm than when the thickness t3 is 3 nm or more. The thickness t3 is, for example, 3 nm or more. In other words, in the solid state imaging device 110 according to the first embodiment, it is possible to suppress the amount An of the dark current by adjusting the thickness t3 of the third layer 30.

FIG. 3B shows a sensitivity Ls of the solid state imaging device 110. The horizontal axis of FIG. 3B is the thickness t3 of the third layer 30. The vertical axis of FIG. 3B is the sensitivity Ls.

As shown in FIG. 3B, the sensitivity Ls decreases when the value of the thickness t3 becomes large. The thickness t3 is, for example, 15 nm or less. The thickness t3 is, for example, not less than 3 nm and not more than 15 nm.

FIG. 3C shows the sensitivity Ls of the solid state imaging device 110. The horizontal axis of FIG. 3C is a thickness t1 of the first layer 10. The vertical axis of FIG. 3C is the sensitivity Ls.

As shown in FIG. 3C, the sensitivity Ls is the highest when the thickness t1 is 50 nm. The thickness t1 is, for example, not less than 20 nm and not more than 100 nm.

Thus, according to the first embodiment, the solid state imaging device 110 having good characteristics can be provided.

### Second Embodiment

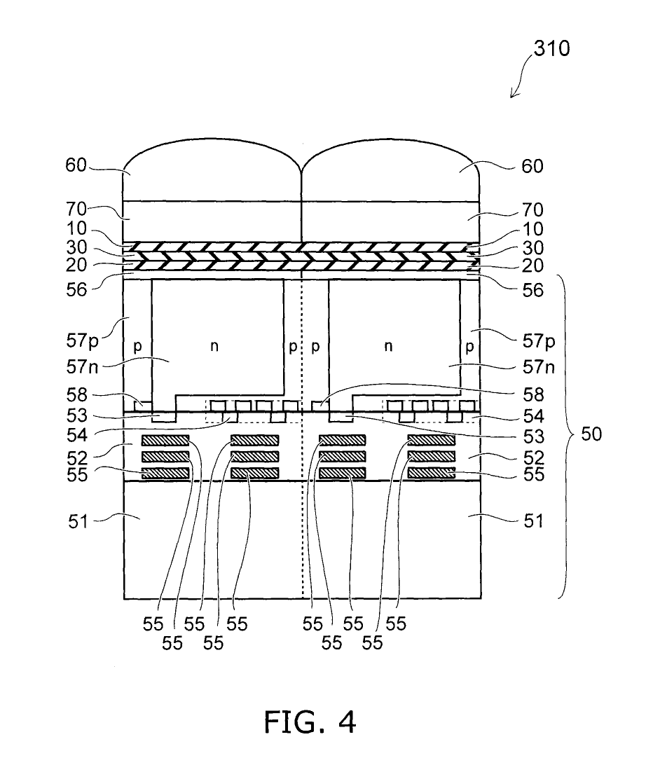

FIG. 4 is a schematic cross-sectional view showing a solid state imaging device according to a second embodiment.

As shown in FIG. 4, the first layer 10, the second layer 20, the third layer 30, the semiconductor layer 50, a microlens 60, and a color filter layer 70 are provided in the solid state imaging device 310 according to the embodiment. The first layer 10, the second layer 20, and the third layer 30 are similar to those of the solid state imaging device 110; and a description is omitted.

The microlens 60 is provided at the surface of the first layer 10 on the side opposite to the surface where the third layer 30 is provided. The color filter layer 70 is provided between the first layer 10 and the microlens 60. The microlens 60 condenses light. The color filter layer 70 separates the light into multiple wavelength regions.

In the example, a support substrate 51, an inter-layer insulating layer 52, a transfer transistor 53, a transistor group 54, a multilayered interconnect 55, a hole layer 56, an n-type diffusion layer 57n, a p-type region 57p, and a floating diffusion layer 58 are provided in the semiconductor layer 50. The support substrate 51 is provided on the same side of the second layer 20 as the semiconductor layer 50. The inter-layer insulating layer 52 is provided between the second layer 20 and the support substrate 51. The transfer transistor 53, the transistor group 54, and the multilayered interconnect 55 are provided inside the inter-layer insulating layer 52. For example, an amplifier transistor, a reset transistor, and an address transistor are provided in the transistor group 54. The hole layer 56 is provided between the second layer 20 and the inter-layer insulating layer 52. The n-type diffusion layer 57n is provided between the hole layer 56 and the inter-layer insulating layer 52. The p-type region 57p is provided between the hole layer 56 and the inter-layer insulating layer 52 adjacent to the n-type diffusion layer 57n. The floating diffusion layer 58 is provided between the p-type region 57p and the inter-layer insulating layer 52.

The n-type diffusion layer 57n and the p-type region 57p perform photoelectric conversion. The n-type diffusion layer 57n stores the signal electrons generated by the photoelectric conversion. The transfer transistor 53 moves the signal electrons stored in the n-type diffusion layer 57n to the floating diffusion layer 58. The floating diffusion layer 58 is connected to the amplifier transistor. The amplifier transistor amplifies the signal electrons. The amplifier transistor outputs the amplified electron signal to the multilayered interconnect 55. The address transistor controls the timing of the amplifier transistor outputting the signal electrons. The reset transistor controls the initial states of the floating diffusion layer 58 and the amplifier transistor. The hole layer 56 stores the holes 50h. According to the embodiment, a solid state imaging device having good characteristics can be provided.

### Third Embodiment

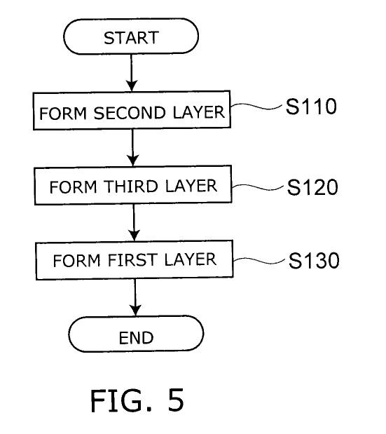

FIG. 5 is a flowchart showing a method for manufacturing a solid state imaging device according to a third embodiment.

As shown in FIG. 5, the second layer 20 that includes a metal oxide is formed on the semiconductor layer 50 that performs the photoelectric conversion (step S110). The second layer 20 has the second refractive index.

The third layer 30 that includes the element bonding covalently with oxygen is formed on the second layer 20 (step S120). The third layer 30 has the third refractive index.

The first layer 10 is formed on the third layer 30 (step S130). The refractive index (the first refractive index) of the first layer 10 is not less than the second refractive index and not less than the third refractive index. Thereby, the first layer 10 is a low reflectance layer.

In the embodiment, the third layer 30 is formed on the second layer 20. Thereby, the state of the negative charge 20e being stored in the second layer 20 is maintained. The holes 50h are maintained in the state of being stored in the semiconductor layer 50. Thereby, the dark current amount can be suppressed. In the embodiment, the first layer 10 is formed on the third layer 30. Thereby, the sensitivity of the solid state imaging device can be increased.

According to the embodiment, a method for manufacturing a solid state imaging device having good characteristics can be provided.

Hereinabove, embodiments of the invention are described with reference to specific examples. However, the invention is not limited to these specific examples. For example, one skilled in the art may similarly practice the invention by appropriately selecting specific configurations of components included in the solid state imaging device such as the semiconductor layer, the microlens, the color filter layer, etc., from known art; and such practice is within the scope of the invention to the extent that similar effects can be obtained.

Further, any two or more components of the specific examples may be combined within the extent of technical feasibility and are included in the scope of the invention to the extent that the purport of the invention is included.

Moreover, all solid state imaging device practicable by an appropriate design modification by one skilled in the art based on solid state imaging device described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A solid state imaging device, comprising:
a semiconductor layer performing photoelectric conversion;
a first layer having a first refractive index;
a second layer provided between the first layer and the semiconductor layer, the second layer including a metal oxide and having a second refractive index not greater than the first refractive index; and
a third layer provided between the first layer and the second layer, the third layer having a third refractive index and including an element bonding covalently with oxygen, the third refractive index not being greater than the first refractive index.

2. The device according to claim 1, wherein the third layer is formed using chemical vapor deposition.

3. The device according to claim 1, wherein a thickness of the third layer is not less than 3 nanometers and not more than 15 nanometers.

4. The device according to claim 1, wherein the second layer includes at least one of hafnium oxide, zirconium oxide, aluminum oxide, titanium oxide, or tantalum oxide.

5. The device according to claim 1, wherein the first layer includes a substance having a refractive index not less than 2.

6. The device according to claim 1, wherein the first layer includes one of titanium oxide or tantalum oxide.

7. The device according to claim 1, wherein the third layer includes at least one of silicon oxide, silicon nitride, or silicon oxynitride.

8. The device according to claim 1, wherein a thickness of the first layer is not less than 20 nanometers and not more than 100 nanometers.

9. The device according to claim 1, wherein the third layer is formed using atomic layer deposition.

10. The device according to claim 1, wherein the first layer is formed using physical vapor deposition.

11. The device according to claim 1, wherein the semiconductor layer stores a hole.

12. The device according to claim 1, wherein the second layer stores a negative charge.

13. The device according to claim 1, wherein a thickness of the third layer is not less than 3 nanometers.

14. The device according to claim 1, wherein a thickness of the third layer is not more than 15 nanometers.

15. The device according to claim 1, wherein a thickness of the first layer is 50 nanometers.

16. A method for manufacturing a solid state imaging device, comprising:
forming a second layer on a semiconductor layer performing photoelectric conversion, the second layer having a second refractive index and including a metal oxide;
forming a third layer on the second layer, the third layer having a third refractive index and including an element bonding covalently with oxygen; and
forming a first layer on the third layer, the first layer having a first refractive index not less than the second refractive index and not less than the third refractive index.

17. The method according to claim 16, wherein the third layer is formed using chemical vapor deposition.

18. The method according to claim 16, wherein a thickness of the third layer is not less than 3 nanometers and not more than 15 nanometers.

19. The method according to claim 16, wherein the second layer includes at least one of hafnium oxide, zirconium oxide, aluminum oxide, titanium oxide, or tantalum oxide.

20. The method according to claim 16, wherein the first layer includes a substance having a refractive index not less than 2.
